(19) United States
(12) Patent Application Publication
(10) Pub. No.: US 2022/0068169 A1
(43) Pub. Date: Mar. 3, 2022

(54) DISPLAY APPARATUS

(71) Applicant: LG DISPLAY CO., LTD., Seoul (KR)

(72) Inventors: Gyujae YOHN, Seoul (KR); MinSeok KIM, Seoul (KR)

(73) Assignee: LG DISPLAY CO., LTD., Seoul (KR)

(21) Appl. No.: 17/410,804

(22) Filed: Aug. 24, 2021

(30) Foreign Application Priority Data
Sep. 1, 2020 (KR) 10-2020-0111155

(51) Int. Cl. G09F 9/30; H01L 27/32; H01L 51/52

(52) U.S. Cl. CPC G09F 9/301; H01L 27/3262; H01L 2251/306; H01L 2251/5338; H01L 2251/308; H01L 51/5284

(57) ABSTRACT

According to an exemplary embodiment of the present disclosure, a display apparatus includes a display panel which is divided into a display area and a non-display area and includes a substrate, a pixel unit transistor which is disposed above the substrate and provided in the display area and a gate in panel (GIP) transistor which is provided in the non-display area, a conductive pattern which is disposed below the substrate and is disposed in an edge area of the display area and the non-display area and which is grounded and a barrier film which is disposed below the substrate and the conductive pattern. By doing this, an edge burn-in due to the polarization may be improved.

### CROSS-REFERENCE TO RELATED APPLICATIONS

This application claims the priority of Korean Patent Application No. 10-2020-0111155 filed on Sep. 1, 2020, in the Korean Intellectual Property Office, the disclosure of which is incorporated herein by reference.

### BACKGROUND

### Technical Field

The present disclosure relates to a display field, and more particularly, to a display apparatus such as a rollable display apparatus.

### Discussion of the Related Art

As display devices which are used for a monitor of a computer, a television, or a cellular phone, there are an organic light emitting display device (OLED) which is a self-emitting device and a liquid crystal display device (LCD) which requires a separate light source, and the like.

An applicable range of the display device is diversified to personal digital assistants as well as monitors of computers and televisions and a display device with a large display area and a reduced volume and weight is being studied.

Recently, a rollable display apparatus which is manufactured by forming a display element and a wiring line on a flexible substrate which is formed of a plastic material such as polyimide (PI) which is a flexible material so as to be capable of displaying images even though the display apparatus is rolled is getting attention as a next generation display apparatus.

### SUMMARY

Accordingly, embodiments of the present disclosure are directed to a display apparatus that substantially obviates one or more of the problems due to limitations and disadvantages of the related art.

An aspect of the present disclosure is to provide a display apparatus that may improve edge burn-in in a display apparatus such as a flexible display apparatus based on a polyimide substrate.

Another aspect of the present disclosure is to provide a display apparatus that may suppress a driving failure of a gate in panel (GIP) unit in a display apparatus such as a flexible display apparatus based on a polyimide substrate.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display apparatus comprises a display panel which is divided into a display area and a non-display area and includes a substrate, a pixel unit transistor which is disposed above the substrate and provided in the display area and a gate in panel (GIP) transistor which is provided in the non-display area, a conductive pattern which is disposed below the substrate and is disposed in an edge area of the display area and the non-display area and which is grounded and a barrier film which is disposed below the substrate and the conductive pattern.

In another aspect, a display apparatus comprises a display panel which is divided into a display area and a non-display area and includes a substrate, a pixel unit transistor which is disposed above the substrate and provided in the display area and a gate in panel (GIP) transistor which is provided in a GIP area of the non-display area, a conductive pattern which is disposed on a side surface of the substrate and is disposed in an edge area of the display area and the non-display area and which is grounded and a barrier film which is disposed below the substrate and the conductive pattern.

In still another aspect, a display apparatus comprises a display panel which is divided into a display area and a non-display area and includes a substrate, a GIP transistor which is disposed above the substrate and is provided in a GIP area of the non-display area, a groove provided in the substrate below the GIP transistor and a filling layer provided in the groove.

Other detailed matters of the exemplary embodiments are included in the detailed description and the drawings.

According to the present disclosure, an edge spot due to polarization may be improved by offsetting positive charges in a polyimide substrate in an edge area of the display panel.

Further, according to the present disclosure, a fluctuation of a threshold voltage Vth of a transistor in a gate in panel (GIP) region is improved and the drop of the high potential power voltage is improved to improve a reliability of a driving circuit.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIGS. 1A and 1B are perspective views of a display apparatus according to a first exemplary embodiment of the present disclosure;

FIG. 2 is a plan view of a display apparatus according to a first exemplary embodiment of the present disclosure;

FIG. 3 is a cross-sectional view taken along the line II-II′ of FIG. 2;

FIG. 4 is a schematic plan view of a display panel according to a first exemplary embodiment of the present disclosure;

FIGS. 5A and 5B are enlarged views of a region A of FIG. 4;

FIG. 6 is a schematic cross-sectional view of a display panel according to a first exemplary embodiment of the present disclosure;

FIG. 7 is a cross-sectional view of a part of a sub pixel according to a first exemplary embodiment of the present disclosure;

FIG. 8 is a schematic cross-sectional view of a display panel according to a second exemplary embodiment of the present disclosure;

FIG. 9 is a schematic cross-sectional view of a display panel according to a third exemplary embodiment of the present disclosure;

FIG. 10 is a schematic cross-sectional view of a display panel according to a fourth exemplary embodiment of the present disclosure;

FIG. 11 is a schematic cross-sectional view of a display panel according to a fifth exemplary embodiment of the present disclosure;

FIG. 12 is a schematic plan view of a display panel according to a sixth exemplary embodiment of the present disclosure;

FIG. 13 is a cross-sectional view of a part of a GIP area according to a sixth exemplary embodiment of the present disclosure;

FIGS. 14A to 14C are cross-sectional views sequentially illustrating a manufacturing method of FIG. 13;

FIG. 15 is a cross-sectional view of a part of a GIP area according to a seventh exemplary embodiment of the present disclosure;

FIGS. 16A to 16C are cross-sectional views sequentially illustrating a manufacturing method of FIG. 15;

FIG. 17 is a schematic plan view of a display panel according to an eighth exemplary embodiment of the present disclosure; and

FIG. 18 is a schematic plan view of a display panel according to a ninth exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure. Therefore, the present disclosure will be defined only by the scope of the appended claims.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

First, a rollable display apparatus may also be referred to as a display apparatus which is capable of displaying images even though the display apparatus is rolled. The rollable display apparatus may have a high flexibility as compared with a general display apparatus of the related art. Depending on whether to use a rollable display apparatus, a shape of the rollable display apparatus may freely vary. Specifically, when the rollable display apparatus is not used, the rollable display apparatus is rolled to be stored with a reduced volume. In contrast, when the rollable display apparatus is used, the rolled rollable display apparatus is unrolled to be used

However, the present disclosure is not limited to a rollable display apparatus but may be applied to all plastic-based display apparatuses such as a foldable display apparatus. Hereinafter, for the convenience of description, a rollable display apparatus will be described as an example of the display apparatus.

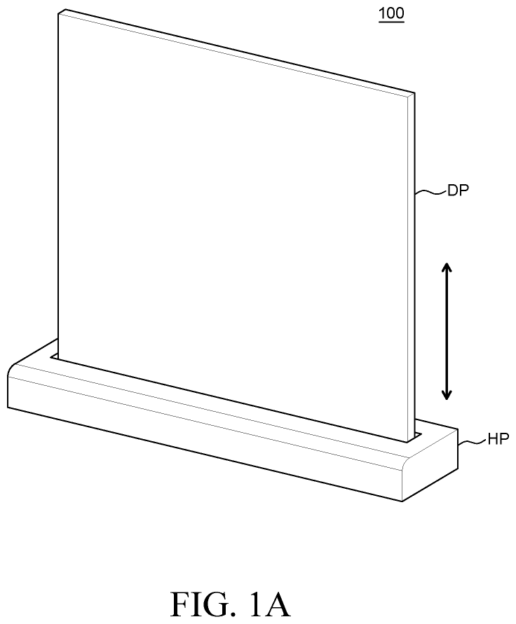

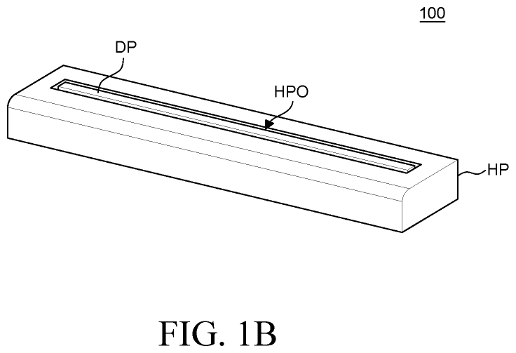

FIGS. 1A and 1B are perspective views of a display apparatus according to a first exemplary embodiment of the present disclosure.

Referring to FIGS. 1A and 1B, a display apparatus 100 according to a first exemplary embodiment of the present disclosure includes a display unit DP and a housing unit HP.

The display unit DP is a configuration for displaying images to a user and for example, in the display unit DP, a display element and a circuit, a wiring line, a component, and the like for driving the display element may be disposed.

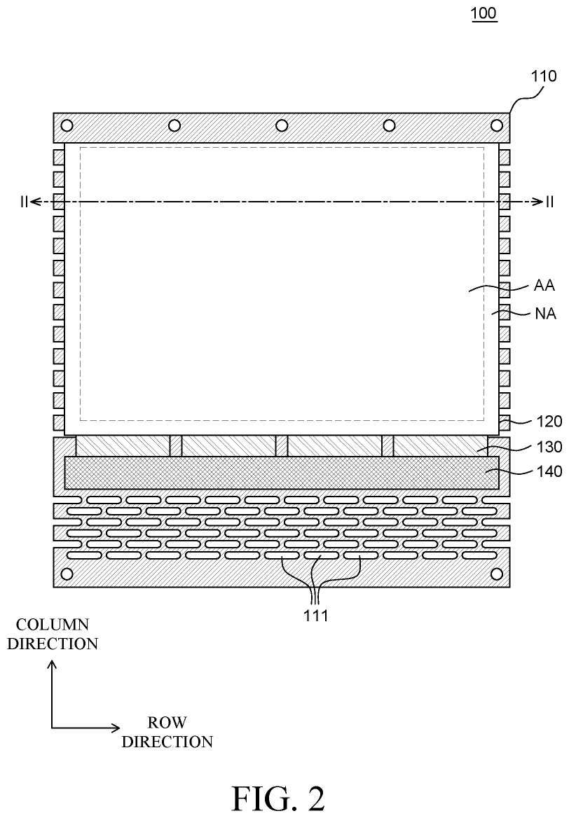

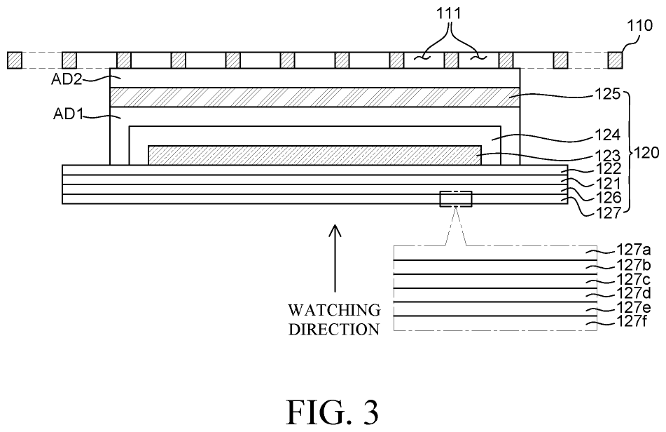

As described above, the display apparatus 100 according to the first exemplary embodiment of the present disclosure is a rollable display apparatus 100 and the display unit DP may be configured to be wound and unwound. For example, the display unit DP according to the first exemplary embodiment of the present disclosure may be formed of a display panel and a back cover each having flexibility to be wound or unwound. The display unit DP will be described below in more detail with reference to FIGS. 2 and 3.

The housing unit HP is a case in which the display unit DP is accommodated. The display unit DP may be wound to be accommodated in the housing unit HP and the display unit DP may be unwound to be disposed at the outside of the housing unit HP.

The housing unit HP has an opening HPO to allow the display unit DP to move to the inside and the outside of the housing unit HP. The display unit DP may move in a vertical direction by passing through the opening HPO of the housing unit HP.

The display unit DP of the display apparatus 100 may be switched from a fully unwound state to a fully wound state or from a fully wound state to a fully unwound state.

FIG. 1A illustrates the display unit DP of the display apparatus 100 which is fully unwound as an example and in the fully unwound state, the display unit DP of the display apparatus 100 is disposed at the outside of the housing unit HP. That is, in order for a user to watch images through the display apparatus 100, when the display unit DP is unwound to be disposed at the outside of the housing unit HP as much as possible and cannot be further unwound, it may be defined as a fully unwound state.

FIG. 1B illustrates the display unit DP of the display apparatus 100 which is fully wound as an example and in the fully wound state, the display unit DP of the display apparatus 100 is accommodated in the housing unit HP and cannot be further wound. That is, when the user does not watch the images through the display apparatus 100, it is advantageous from the viewpoint of an outer appearance that the display unit DP is not disposed at the outside of the housing unit HP. Therefore, when the display unit DP is wound to be accommodated in the housing unit HP, it is defined as a fully wound state.

When the display unit DP is in a fully wound state to be accommodated in the housing unit HP, a volume of the display apparatus 100 is reduced and the display apparatus 100 may be easily carried.

In order to switch the display unit DP to a fully unwound state or a fully wound state, a driving unit which winds or unwinds the display unit DP may be disposed.

FIG. 2 is a plan view of a display apparatus according to a first exemplary embodiment of the present disclosure.

FIG. 3 is a cross-sectional view taken along the line II-II′ of FIG. 2.

Referring to FIGS. 2 and 3, the display unit DP according to the first exemplary embodiment of the present disclosure includes a back cover 110, a display panel 120, a flexible film 130, and a printed circuit board 140.

The display panel 120 is a panel for displaying images to a user.

The display panel 120 may include a display element which displays images, a driving element which drives the display element, and wiring lines which transmit various signals to the display element and the driving element. The display element may be defined in different ways depending on a type of the display panel 120. For example, when the display panel 120 is an organic light emitting display panel, the display element may be an organic light emitting diode which includes an anode, an organic light emitting layer, and a cathode. For example, when the display panel 120 is a liquid crystal display panel, the display element may be a liquid crystal display element. Hereinafter, even though the display panel 120 is assumed as an organic light emitting display panel, the display panel 120 is not limited to the organic light emitting display panel. Further, since the display apparatus 100 according to the first exemplary embodiment of the present disclosure is a rollable display apparatus, the display panel 120 may be implemented as a flexible display panel to be wound around or unwound from the roller.

The display panel 120 includes a display area AA and a non-display area NA.

The display area AA is an area where images are displayed in the display panel 120.

In the display area AA, a plurality of sub pixels which configures the plurality of pixels and a circuit for driving a plurality of sub pixels may be disposed. The plurality of sub pixels is minimum units which configure the display area AA and a display element may be disposed in each of the plurality of sub pixels. The plurality of sub pixels may configure a pixel. For example, an organic light emitting diode which includes an anode, an organic light emitting layer, and a cathode may be disposed in each of the plurality of sub pixels, but it is not limited thereto. Further, a circuit for driving the plurality of sub pixels may include a driving element, a wiring line, and the like. For example, the circuit may be configured by a thin film transistor, a storage capacitor, a gate line, a data line, and the like, but is not limited thereto.

The non-display area NA is an area where no image is displayed.

In the non-display area NA, various wiring lines, circuits, and the like for driving the organic light emitting diode of the display area AA are disposed. For example, in the non-display area NA, a link line which transmits signals to the plurality of sub pixels and circuits of the display area AA or a driving IC such as a gate driver IC or a data driver IC may be disposed, but it is not limited thereto.

The flexible film 130 is a film in which various components are disposed on a base film having a malleability. Specifically, the flexible film 130 is a film which supplies a signal to the plurality of sub pixels and the circuits of the display area AA and is electrically connected to the display panel 120. The flexible film 130 is disposed at one end of the non-display area NA of the display panel 120 to supply a power voltage or a data voltage to the plurality of sub pixels and the circuits of the display area AA. Even though four flexible films 130 are illustrated in FIG. 2, the number of flexible films 130 may vary depending on the design and is not limited thereto.

In the meantime, for example, a driving IC such as a gate driver IC or a data driver IC may be disposed on the flexible film 130. The driving IC is a component which processes data for displaying images and a driving signal for processing the data. The driving IC may be disposed by a chip on glass (COG), a chip on film (COF), a tape carrier package (TCP), or the like depending on a mounting method. However, for the convenience of description, it is described that the driving IC is mounted on the flexible film 130 by a chip on film manner but is not limited thereto.

The printed circuit board 140 is disposed at one end of the flexible film 130 to be connected to the flexible film 130. The printed circuit board 140 is a component which supplies signals to the driving IC. The printed circuit board 140 supplies various signals such as a driving signal or a data signal to the driving IC. For example, a data driver which generates data signals may be mounted in the printed circuit board 140 and the generated data signal may be supplied to the plurality of sub pixels and the circuit of the display panel 120 through the flexible film 130. In the meantime, even though one printed circuit board 140 is illustrated in FIG. 2, the number of printed circuit boards 140 may vary depending on the design but is not limited thereto.

A flexible printed circuit board which is connected to the printed circuit board 140 may be further disposed. For example, the printed circuit board 140 may be referred to as a source printed circuit board S-PCB on which the data driver is mounted, and the flexible printed circuit board connected to the printed circuit board 140 may be referred to as a control printed circuit board C-PCB on which the timing controller is mounted. For example, the flexible printed circuit board may be disposed in the roller or disposed in the housing unit HP at the outside of the roller or disposed to be in direct contact with the printed circuit board 140.

The back cover 110 is disposed on rear surfaces of the display panel 120, the flexible film 130, and the printed circuit board 140 to support the display panel 120, the flexible film 130, and the printed circuit board 140. Therefore, a size of the back cover 110 may be larger than a size of the display panel 120. Therefore, the back cover 110 may protect other configurations of the display unit DP from the outside. Even though the back cover 110 is formed of a material having a rigidity, at least a part of the back cover 110 may have a flexibility to be wound or unwound together with the display panel 120. For example, the back cover 110 may be formed of a metal material such as steel use stainless SUS or invar or plastic. However, as long as a material of the back cover 110 satisfies physical conditions such as a thermal strain amount, a radius of curvature, and a rigidity, various materials may be used, and is not limited thereto.

Referring to FIG. 3, the display panel 120 includes a substrate 121, a buffer layer 122, a pixel unit 123, an encapsulation layer 124, an encapsulation substrate 125, a barrier film 126, and a polarizing plate 127.

The substrate 121 is a base member which supports various components of the display panel 120 and may be configured by an insulating material. The substrate 121 may be formed of a material having a flexibility to allow the display panel 120 to be wound or unwound and for example, may be formed of a plastic material such as polyimide (PI).

The buffer layer 122 may suppress moisture and/or oxygen which permeates from the outside of the substrate 121 from being spread. The buffer layer 122 may be configured by a single layer or a double layer of silicon oxide SiOx and silicon nitride SiNx but is not limited thereto.

The pixel unit 123 includes a plurality of organic light emitting diodes and a pixel driving circuit for driving the organic light emitting diodes. The pixel unit 123 may be an area corresponding to the display area AA. The organic light emitting diode may include an anode, an organic light emitting layer, and a cathode.

The anode may supply holes to the organic light emitting layer and be formed of a conductive material having a high work function. For example, the anode may be formed of tin oxide (TO), indium tin oxide (ITO), indium zinc oxide (IZO), indium zinc tin oxide (ITZO), or the like, but is not limited thereto.

The organic light emitting layer is supplied with holes from the anode and supplied with electrons from the cathode to emit light. The organic light emitting layer may be formed of a red organic light emitting layer, a green organic light emitting layer, a blue organic light emitting layer, and a white organic light emitting layer depending on a color of light emitted from the organic light emitting layer. When the organic light emitting layer is a white organic light emitting layer, color filters having various colors may be additionally disposed.

The cathode may supply electrons to the organic light emitting layer and be formed of a conductive material having a low work function. For example, the cathode may be formed of any one or more selected from a group consisting of metals, such as magnesium (Mg), silver (Ag), and aluminum (Al), and an alloy thereof, but is not limited thereto.

The display panel 120 may be configured by a top emission type or a bottom emission type, depending on an emission direction of light which is emitted from the organic light emitting diode.

According to the top emission type, light emitted from the organic light emitting diode is emitted to an upper portion of the substrate 121 on which the organic light emitting diode is formed. In the case of the top emission type, a reflective layer may be formed below the anode to allow the light emitted from the organic light emitting diode to travel to the upper portion of the substrate 121, that is, toward the cathode.

According to the bottom emission type, light emitted from the organic light emitting diode is emitted to a lower portion of the substrate 121 on which the organic light emitting diode is formed. In the case of the bottom emission type, the anode may be formed only of a transparent conductive material and the cathode may be formed of the metal material having a high reflectance to allow the light emitted from the organic light emitting diode to travel to the lower portion of the substrate 121.

Hereinafter, for the convenience of description, the description will be made by assuming that the display apparatus 100 according to a first exemplary embodiment of the present disclosure is a bottom emission type display apparatus, but it is not limited thereto.

A circuit for driving the organic light emitting diode is disposed in the pixel unit 123. The circuit may be formed of a thin film transistor, a storage capacitor, a gate line, a data line, a power line, and the like, but it may vary in various forms depending on the design of the display apparatus 100.

The encapsulation layer 124 which covers the pixel unit 123 is disposed above the pixel unit 123. The encapsulation layer 124 seals the organic light emitting diode of the pixel unit 123. The encapsulation layer 124 may protect the organic light emitting diode of the pixel unit 123 from moisture, oxygen, and impacts of the outside. The encapsulation layer 124 may be formed by alternately laminating a plurality of inorganic layers and a plurality of organic layers. For example, the inorganic layer may be formed of an inorganic material such as silicon nitride SiNx, silicon oxide SiOx, and aluminum oxide AlOx and the organic layer may be formed of epoxy or acrylic polymer, but they are not limited thereto.

The encapsulation substrate 125 is disposed above the encapsulation layer 124. The encapsulation substrate 125 protects the organic light emitting diode of the pixel unit 123 together with the encapsulation layer 124. The encapsulation substrate 125 may protect the organic light emitting diode of the pixel unit 123 from moisture, oxygen, and impacts of the outside. The encapsulation substrate 125 may be formed of a metal material, which has a high corrosion resistance and is easily processed in the form of a foil or a thin film, such as aluminum (Al), nickel (Ni), chromium (Cr), and an alloy material of iron (Fe) and nickel. Therefore, as the encapsulation substrate 125 is formed of a metal material, the encapsulation substrate 125 may be implemented by an ultra-thin film and have a high resistance against external impacts and scratches.

A first adhesive layer AD1 may be disposed between the encapsulation layer 124 and the encapsulation substrate 125. The first adhesive layer AD1 may bond the encapsulation layer 124 and the encapsulation substrate 125 to each other. The first adhesive layer AD1 is formed of a material having adhesiveness and may be a thermosetting or natural curable type adhesive. For example, the first adhesive layer AD1 may be formed of an optical clear adhesive (OCA), a pressure sensitive adhesive (PSA), or the like, but is not limited thereto.

In the meantime, the first adhesive layer AD1 may be disposed so as to enclose the encapsulation layer 124 and the pixel unit 123. That is, the pixel unit 123 may be sealed by the buffer layer 122 and the encapsulation layer 124, and the encapsulation layer 124 and the pixel unit 123 may be sealed by the buffer layer 122 and the first adhesive layer AD1. The first adhesive layer AD1 may protect the organic light emitting diode of the pixel unit 123 from moisture, oxygen, and impacts of the outside together with the encapsulation layer 124 and the encapsulation substrate 125. The first adhesive layer AD1 may further include an absorbent. The absorbent may be particles having hygroscopicity and absorb moisture and oxygen from the outside to minimize permeation of the moisture and oxygen into the pixel unit 123.

The barrier film 126 is disposed on a lower surface of the substrate 121. The barrier film 126 may protect the display panel 120 from impacts, moisture, and heat from the outside. The barrier film 126 may be configured by polymer resin having a characteristic which is light and unbreakable. For example, the barrier film 126 may be configured by cyclo olefin polymer (COP) but is not limited thereto and may also be configured by a material such as polyimide (PI), poly carbonate (PC), and polyethylene terephthalate (PET).

The polarizing plate 127 is disposed on a lower surface of the barrier film 126.

The polarizing plate 127 is a configuration which suppresses external light incident onto the display apparatus 100 from being reflected to be visible. For example, the polarizing plate 127 may include a surface layer 127f, a first protective layer 127e, a polarization layer 127d, a second protective layer 127c, a phase retardation layer 127b, and an adhesive layer 127a.

The surface layer 127f is disposed at the outermost side of the polarizing plate 127 to enhance a mechanical strength of the polarizing plate 127 and suppress the glare and reflection so that the visibility of the display apparatus 100 may be improved. The surface layer 127f may be formed with a layer or a film formed by a surface processing method such as anti-glare (AG), semi glare (SG), low reflection (LR), and anti-glare and low reflection (AGLR), but is not limited thereto.

The adhesive layer 127a is disposed on an uppermost side of the polarizing plate 127 to bond the polarizing plate 127 to the barrier film 126. The adhesive layer 127a may be formed of, for example, a pressure sensitive adhesive (PSA), but is not limited thereto.

The phase retardation layer 127b may have a transmission axis of −45 degrees or +45 degrees with respect to an angle at which external light is polarized by the polarization layer 127d. Therefore, external light which is incident onto the phase retardation layer 127b passes through the phase retardation layer 127b to be circularly polarized.

The polarization layer 127d may linearly polarize light incident from the outside of the display apparatus 100. Therefore, the polarization layer 127d may be formed of an oriented film formed of polyvinyl alcohol (PVA)-based polymer film containing iodine or dichroic dye but is not limited thereto.

The first protective layer 127e and the second protective layer 127c may be disposed on both surfaces of the polarization layer 127d. The polarization layer 127d is formed of a polyvinyl alcohol-based material which absorbs moisture so that the first protective layer 127e and the second protective layer 127c are disposed on both surfaces of the polarization layer 127d. Therefore, the damage of the polarization layer 127d due to heat or moisture may be suppressed. The first protective layer 127e and the second protective layer 127c may be formed of a material having no phase difference so as not to affect the polarized state of the polarization layer 127d. For example, the first protective layer 127e and the second protective layer 127c may be formed of a material such as triacetyl cellulose (TAC), but is not limited thereto.

The back cover 110 may be disposed above the encapsulation substrate 125. The back cover 110 is disposed to be in contact with the encapsulation substrate 125 of the display panel 120 to protect the display panel 120. In order to protect the display panel 120, the back cover 110 may be formed of a material having a rigidity.

In the meantime, the back cover 110 may include a plurality of openings 111.

The plurality of openings 111 may allow the back cover 110 to have flexibility. The plurality of openings 111 may be flexibly deformed and allow the back cover 110 to be wound around the roller or unwound from the roller together with the display panel 120.

A second adhesive layer AD2 may be disposed between the encapsulation substrate 125 and the back cover 110. The second adhesive layer AD2 may bond the encapsulation substrate 125 and the back cover 110 to each other. The second adhesive layer AD2 is formed of a material having adhesiveness and may be a thermosetting or natural curable type adhesive. For example, the second adhesive layer AD2 may be formed of an optical clear adhesive (OCA), a pressure sensitive adhesive (PSA), or the like, but is not limited thereto.

Even though in FIG. 3, it is illustrated that the plurality of openings 111 of the back cover 110 is not filled with the second adhesive layer AD2, the second adhesive layer AD2 may be filled in some or all of the plurality of openings 111. If the second adhesive layer AD2 is filled in the plurality of openings 111 of the back cover 110, a contact area between the second adhesive layer AD2 and the back cover 110 is increased so that a separation phenomenon may be avoided.

According to the present disclosure, in the display apparatus such as the flexible display device based on a polyimide substrate, a conductive pattern is formed in an edge area of the display panel to offset positive charges in the substrate such as the polyimide substrate. By doing this, the burn-in of an edge may be improved. Further, according to the present disclosure, a part of the substrate such as the polyimide substrate below the transistor of the gate-in-panel (GIP) unit is removed or a light shielding layer is formed to suppress the driving failure in the GIP area, which will be described in detail with reference to the drawings.

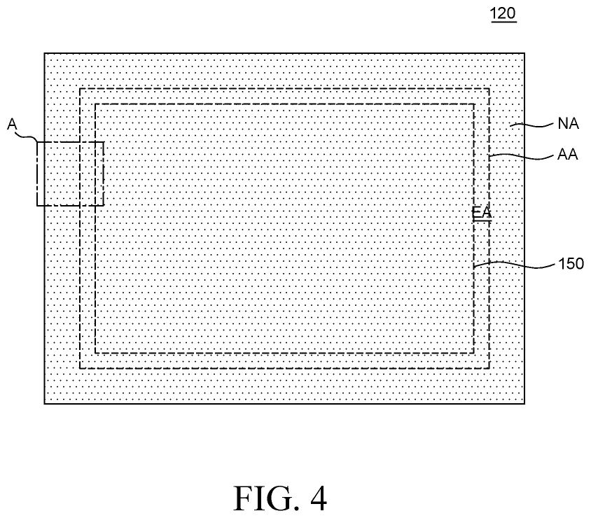

FIG. 4 is a schematic plan view of a display panel according to a first exemplary embodiment of the present disclosure.

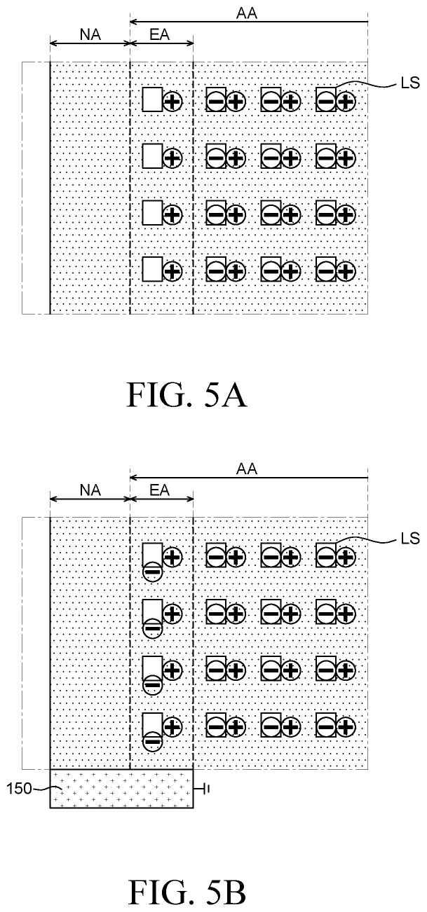

FIGS. 5A and 5B are enlarged views of a region A of FIG. 4.

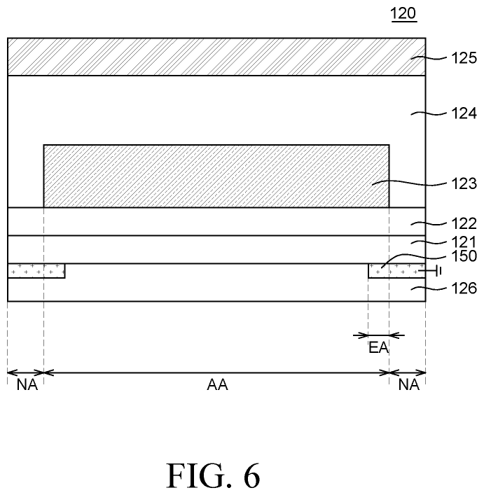

FIG. 6 is a schematic cross-sectional view of a display panel according to a first exemplary embodiment of the present disclosure.

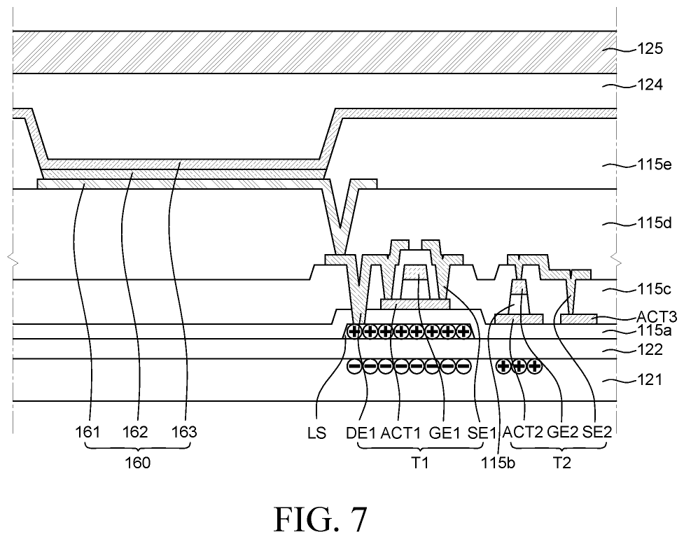

FIG. 7 is a cross-sectional view of a part of a sub pixel according to a first exemplary embodiment of the present disclosure.

FIG. 5A shows a part of a display panel according to a comparative embodiment which does not include a conductive pattern 150 of the present disclosure as an example and FIG. 5B illustrates a part of a display panel of a first exemplary embodiment which includes a conductive pattern 150 of the present disclosure as an example.

In FIG. 6, a polarizing plate is not illustrated for convenience of the description.

Even though in FIG. 7, one first transistor T1, one second transistor T2, and one third transistor are illustrated, it is not limited thereto. Further, in FIG. 7, for the convenience of description, the second transistor T2 and only a part of the third transistor are illustrated.

Referring to FIG. 4, the display panel 120 according to the first exemplary embodiment of the present disclosure may include a display area AA and a non-display area NA.

The display area AA is an area in the display panel 120 where images are displayed and a part of the edge of the display area AA may be defined as an edge area EA.

The edge area EA may have a width of 5 mm inwardly from the edge of the display area AA but is not limited thereto. The width may vary depending on the pixel design and the width of 5 mm may correspond to widths of approximately ten sub pixels.

The edge area EA corresponds to an edge of the display area AA.

The non-display area NA is an area where the images are not displayed, and the non-display area NA may include a GIP area in which a gate driver is disposed.

The non-display area AA may be adjacent to one or more side surfaces of the display area AA.

In FIG. 4, it is illustrated that the non-display area NA encloses a rectangular display area AA as an example. However, a shape of the display area AA and a shape and a placement of the non-display area NA adjacent to the display area AA are not limited to an example illustrated in FIG. 4. The display area AA and the non-display area NA may have shapes suitable for a design of an electronic device including the display apparatus 100. Accordingly, an exemplary shape of the display area AA may include a pentagon, a hexagon, a circle, an oval, or the like.

Each pixel in the display area AA may include a pixel driving circuit. The pixel driving circuit may include one or more switching transistors and one or more driving transistors. Further, the pixel driving circuit may further include one or more sensing transistors. Each pixel driving circuit may be electrically connected to a gate line and a data line in order to communicate with a gate driver and a data driver located in the non-display area NA.

The gate driver and the data driver may be implemented by thin film transistors TFT in the non-display area NA. This driver is referred to as a GIP. Further, some components such as a data driver IC may be mounted on a divided printed circuit board and may be coupled to a connecting interface (a pad, a bump, or a pin) disposed in the non-display area NA by means of a circuit film such as a flexible printed circuit board (FPCB), a chip-on-film (COF), or a tape-carrier-package (TCP).

The display apparatus 100 may further include various additional elements to generate various signals or drive the pixel in the display area AA. The additional elements for driving the pixels may include an inverter circuit, a multiplexer, an electrostatic discharge circuit, or the like. The display apparatus 100 may further include an additional element associated with a function other than a pixel driving function. For example, the display apparatus 100 may include additional elements which provide a touch sensing function, a user authentication function (for example, fingerprint recognition), a multilevel pressure sensing function, a tactile feedback function, or the like. The above-mentioned additional elements may be located in an external circuit which is connected to the non-display area NA and/or the connecting interface.

In the meantime, the display apparatus 100 according to the first exemplary embodiment of the present disclosure forms a conductive pattern 150 in the edge area EA of the display panel 120 to improve an edge burn-in.

That is, the conductive pattern 150 according to the first exemplary embodiment is formed below the substrate 121 in the non-display area NA and the edge area EA and is grounded to offset the positive charges in the substrate 121. Therefore, the edge burn-in is improved.

For example, the conductive pattern 150 according to the first exemplary embodiment of the present disclosure may be disposed at the left and right sides of the display panel 120 where the GIP area is disposed with a stripe shape but is not limited thereto. The conductive pattern 150 of the present disclosure may be disposed at the entire edge of the display panel 120 in the form of a rectangular frame.

Specifically, in the flexible display apparatus such as the flexible display apparatus in which polyimide is applied as a substrate, an edge burn-in of the display panel becomes an issue. For example, in the rollable display apparatus, polyimide is used as the substrate for ensuring the rolling.

The polyimide is basically configured by solvent and solid and mobile charges are generated due to a chemical bond after curing the polyimide. Referring to FIG. 5A, an electric field is applied (driven) to the display panel, the mobile charges of the polyimide move. In the display apparatus, an electric field difference is structurally caused depending on the presence of a light shielding layer LS between the display area AA and the non-display area NA. That is, referring to FIG. 7, when the display panel 120 is driven, a (+) electric field may be formed on the light shielding layer LS below the first transistor T1 and a polarized mobile charge is formed on a surface of the polyimide substrate 121 due to the electric field. (−) charges (i.e., negative charges) are collected on the surface of the substrate 121 below the light shielding layer LS and relatively, (+) charges (i.e., positive charges) are collected in the other area. In contrast, the light shielding layer is not provided or less provided in the GIP area of the non-display area NA and (+) and (−) signals are alternately applied.

At the time of initial and long-term driving, (−) charges move below the light shielding layer LS having a strong electric field and (+) charges are trapped in the other area. As compared with the edge area EA, the entire display panel 120 forms an electrical equilibrium state by the strong electric field of the other display area AA so that the edge burn-in does not occur. For reference, “the other display area AA” refers to a display area AA excluding the edge area EA from the display area AA, for the convenience of description.

However, in the case of re-driving after completing the driving, (+) charges trapped in the edge area EA meet (−) charges which are generated at the time of the re-driving to be offset (neutral) and regenerated (+) charges move in the vicinity of the lower portion of the light shielding layer LS. By doing this, negative shift of Vth of the second transistor T2 is caused to recognize the burn-in due to a luminance difference between the edge area EA and the other display area AA.

Accordingly, according to the present disclosure, referring to FIG. 6, the conductive pattern 150 is formed and grounded below the substrate 121 of the edge area EA of the display panel 120 to offset the (+) charges trapped in the edge area EA.

Referring to FIGS. 6 and 7, the conductive pattern 150 of the first exemplary embodiment of the present disclosure may be formed below the substrate 121 in the non-display area NA and the edge area EA.

The conductive pattern 150 may be configured by a conductive tape but is not limited thereto.

After the laser lift off (LLO) process, the conductive tape may be laminated at an outer periphery of the display panel 120. Thereafter, the barrier film 126 may be laminated.

That is, the display panel 120 according to the first exemplary embodiment of the present disclosure may include a substrate 121 on which thin film transistors T1 and T2 and an organic light emitting diode 160 are disposed, an encapsulation substrate 125, a barrier film 126, and the like.

The substrate 121 may be a glass or plastic substrate. When the substrate is a plastic substrate, polyimide-based or polycarbonate-based materials are used so that the substrate may have a flexibility. Specifically, polyimide may be applied to a high temperature process and may be coated, and thus polyimide may be frequently used for the plastic substrate.

The buffer layer 122 is a functional layer which protects the transistors from impurities such as alkali ions, moisture and/or oxygen leaked from the substrate 121 or lower layers thereof. The buffer layer 122 may be configured by a single layer of silicon oxide (SiOx), silicon nitride (SiNx), or multi-layers thereof, but is not limited thereto. The buffer layer 122 may include a multi buffer layer and/or an active buffer layer. The multi-buffer layer may be configured by alternately laminating silicon oxide (SiOx) and silicon nitride (SiNx) and perform a function of delaying the diffusion of moisture and/or oxygen permeating into the substrate 121. The active buffer layer performs a function of protecting active layers ACT1, ACT2, and ACT3 of the transistors T1 and T2 and blocking various types of defects flowing from the substrate 121.

The pixel unit 123 includes an organic light emitting diode 160 and a pixel driving circuit for driving the organic light emitting diode 160. The pixel unit 123 may be an area corresponding to the display area AA.

The organic light emitting diode 160 may include an anode 161, an organic layer 162, and a cathode 163.

At least one first transistor T1, second transistor T2, and third transistor may be disposed on the buffer layer 122. The first transistor T1 may be a driving transistor, the second transistor T2 may be a sensing transistor, and the third transistor may be a switching transistor, but are not limited thereto.

The first transistor T1 may include a first active layer ACT1, a first gate electrode GE1, a first source electrode SE1, and a first drain electrode.

The second transistor T2 may include a second active layer ACT2, a second gate electrode GE2, a second source electrode SE2, and a second drain electrode DE2.

The third transistor may include a third active layer ACT3, a third gate electrode, a third source electrode, and a third drain electrode.

The light shielding layer LS may be disposed on the buffer layer 122.

The light shielding layer LS is disposed to overlap the first active layer ACT1 of the first transistor T1 to protect the first transistor T1 from light introduced from the outside or moisture introduced from the outside to minimize the deformation of the device characteristic of the first transistor T1. Even though in FIG. 7, it is illustrated that the light shielding layer LS is electrically connected to the first drain electrode DE1, the light shielding layer LS may be floated, so that it is not limited thereto.

A first insulating layer 115a may be disposed on the light shielding layer LS.

The first insulating layer 115a may be configured as a single layer of silicon nitride SiNx or silicon oxide SiOx or a multi-layer thereof.

The first active layer ACT1, the second active layer ACT2, and the third active layer ACT3 may be disposed on the first insulating layer 115a. The first active layer ACT1, the second active layer ACT2, and the third active layer ACT3 may be formed of an oxide semiconductor material.

However, it is not limited thereto so that the first active layer ACT1, the second active layer ACT2, and the third active layer ACT3 may be formed of an amorphous silicon a-Si or various organic semiconductor materials such as pentacene.

The gate insulating layer 115b is disposed on the first active layer ACT1 and the second active layer ACT2 and the first gate electrode GE1 and the second gate electrode GE2 may be disposed thereon.

The gate insulating layer 115b may be configured as a single layer of silicon nitride SiNx or silicon oxide SiOx or a multi-layer thereof.

The first gate electrode GE1 and the second gate electrode GE2 may be formed of various conductive materials, for example, magnesium (Mg), aluminum (Al), nickel (Ni), chrome (Cr), molybdenum (Mo), tungsten (W), gold (Au), or an alloy thereof, but is not limited thereto.

A second insulating layer 115c may be disposed on the first gate electrode GE1 and the second gate electrode GE2.

The second insulating layer 115c is an interlayer insulating layer and may be formed of an insulating inorganic material such as silicon oxide SiOx or silicon nitride SiNx or an insulating organic material. The second insulating layer 115c and/or the first insulating layer 115a is selectively removed to form a contact hole through which the light shielding layer LS, the second gate electrode GE2, and source and drain regions of the first active layer ACT1 are exposed.

The first source electrode SE1 and the first drain electrode DE1 may be disposed on the second insulating layer 115c. The first source electrode SE1 and the first drain electrode DE1 which are disposed to be spaced apart from each other may be electrically connected to the first active layer ACT1. Further, the first drain electrode DE1 may also be electrically connected to the light shielding layer LS.

The second source electrode SE2 may be disposed on the second insulating layer 115c. The second source electrode SE2 may be electrically connected to the second gate electrode GE2 and the third active layer ACTS.

The third insulating layer 115d may be disposed on the first source electrode SE1, the first drain electrode DE1, and the second source electrode SE2.

The third insulating layer 115d is a planarization layer to protect the transistors T1 and T2 and planarize an upper portion thoseof. The third insulating layer 115d may be configured by various forms to be formed with an organic insulating layer such as benzocyclobutene (BCB) or acryl or an inorganic insulating layer such as silicon oxide (SiOx) or silicon nitride (SiNx) or formed as a single layer or a double layer or multiple layers.

The organic light emitting diode 160 may be disposed on the third insulating layer 115d.

The organic light emitting diode 160 may include an anode 161, an organic layer 162 formed on the anode 161, and a cathode 163 formed on the organic layer 162.

The organic light emitting diode 160 may be configured with a single light-emitting layer structure which emits single light or may be configured with a structure which is configured by a plurality of light emitting layers to emit white light. When the organic light emitting diode 160 emits white light, a color filter may be further provided. The organic light emitting diode 160 may be disposed in the middle of the substrate 101 corresponding to the display area AA.

The anode 161 may be disposed on the third insulating layer 115d. The anode 161 may be electrically connected to the first drain electrode DE1 of the first transistor T1 by means of the contact hole.

The anode 161 supplies holes to the light emitting layer so that the anode may be formed of a conductive material having a high work function. For example, the anode 161 may be formed of a transparent conductive material such as indium tin oxide (ITO) and indium zinc oxide (IZO) but is not limited thereto.

The display apparatus 100 may be implemented as a top emission type or a bottom emission type. When the display apparatus is a top emission type, a reflective layer, which is formed of a metal material having an excellent reflection efficiency such as aluminum (Al) or silver (Ag), may be added below the anode 161. Therefore, light emitted from the light emitting layer is reflected from the anode 161 to be directed to the upper direction, that is, the cathode 163. In contrast, when the display apparatus 100 is a bottom emission type, the anode 161 may be only formed of a transparent conductive material.

The organic layer 162 may be disposed between the anode 161 and the cathode 163.

The organic layer 162 is an area where light is emitted by the coupling of the electrons and holes supplied from the anode 161 and the cathode 163.

In the meantime, various organic light emitting diode structures for improving the efficiency and the lifespan of the organic light emitting diode and reducing power consumption are proposed to improve a quality and a productivity of the organic light emitting display apparatus.

Accordingly, an organic light emitting diode with a tandem structure which uses a plurality of stacks, that is, a lamination of a plurality of electroluminescent units is proposed to implement the improved efficiency and lifespan characteristic, in addition to an organic light emitting diode which applies one stack, that is, one electroluminescent unit (EL unit). However, the present disclosure is not limited to a tandem structure. Hereinafter, for the convenience of description, a tandem structure will be described as an example.

In the organic light emitting diode with a tandem structure, that is, a double stack structure using a lamination of a first electroluminescent unit and a second electroluminescent unit, an emission area where light is emitted by recombination of the electrons and the holes is disposed in each of the first electroluminescent unit and the second electroluminescent unit. Therefore, the light emitted from a first light emitting layer of the first electroluminescent unit and a second light emitting layer of the second electroluminescent unit cause constructive interference to provide high luminance as compared with the organic light emitting diode with a single stack structure.

The stack structure may include a charge generating layer disposed between the anode 161 and the cathode 163, a first stack disposed between the charge generating layer and the anode 161, and a second stack disposed between the cathode 163 and the charge generating layer. The charge generating layer is disposed between the first stack and the second stack to generate charges. The charge generating layer may be formed with a structure in which a p-type charge generating layer and an n-type charge generating layer are laminated. That is, the charge generating layer may be configured by a p-type charge generating layer and an n-type charge generating layer which generate positive charges and negative charges to both directions and substantially serve as an electrode.

Each of the first stack and the second stack includes at least one light emitting layer and may include a common layer between light emitting layers.

A bank 115e may be disposed above the anode 161 and the third insulating layer 115d.

The bank 115e is an insulating layer disposed between the plurality of sub pixels to divide the plurality of sub pixels.

The bank 115e may include an opening which exposes a part of the anode 161. The bank 115e may be an organic insulating material disposed to cover an edge or a border of the anode 161. For example, the bank 115e may be formed of polyimide resin, acrylic resin, or benzocyclobutene (BCB) resin, but is not limited thereto.

The organic layer 162 may be disposed on the anode 161. The organic layer 162 may include a light emitting layer disposed in each of the plurality of sub pixels and a common layer which is commonly disposed in the plurality of sub pixels. The light emitting layer is an organic layer which emits light having a specific color and different light emitting layers are disposed in a first sub pixel, a second sub pixel, and a third sub pixel, respectively. However, the present disclosure is not limited thereto, for example, a plurality of light emitting layers may be provided in all sub pixels to emit white light.

The common layer is an organic layer which is disposed to improve luminous efficiency of the light emitting layer.

The common layer may be formed as one layer over the plurality of sub pixels. That is, the common layers of the plurality of sub pixels are connected to be integrally formed. The common layer may include a hole injection layer, a hole transport layer, an electron transport layer, an electron injection layer, and a charge generating layer, but is not limited thereto.

The cathode 163 is disposed on the organic layer 162.

The cathode 163 is an electrode which supplies electrons to the organic light emitting diode 160.

The cathode 163 may be formed of a material having a low work function. The cathode 163 may include a transparent conductive material. For example, the cathode 163 may be formed of indium tin oxide (ITO), indium zin oxide (IZO), indium gallium zinc oxide (IGZO), or the like. Alternatively, the cathode 163 may include any one of a group consisting of metal materials such as gold (Au), silver (Ag), aluminum (Al), molybdenum (Mo), magnesium (Mg), palladium (Pd), copper (Cu), and an alloy thereof. For example, the cathode 163 may be formed of an alloy of magnesium (Mg) and silver (Ag). Alternatively, the cathode 163 may be configured by laminating a layer formed of a transparent conductive layer such as ITO, IZO, or IGZO and a layer formed of a metal material such as gold (Au), silver (Ag), aluminum (Al), molybdenum (Mo), magnesium (Mg), palladium (Pd), copper (Cu), or an alloy thereof, but is not limited thereto.

The cathode 163 is electrically connected to a low potential power line to be supplied with a low potential power signal.

The encapsulation layer 124 may be disposed on the cathode 163. The encapsulation layer 124 may be disposed above the bank 115e and the organic light emitting diode 160. The encapsulation layer 124 may block the oxygen and moisture which permeate into the display apparatus 100 from the outside. For example, when the display apparatus 100 is exposed to the moisture or oxygen, a pixel shrink phenomenon that the emission area is shrunk occurs or a dead pixel in the emission area is generated. The encapsulation layer 124 may block the oxygen and the moisture to protect the display apparatus 100.

The encapsulation layer 124 may include a first encapsulation layer, a second encapsulation layer, and a third encapsulation layer.

The first encapsulation layer is disposed on the cathode 163 and suppresses the permeation of moisture or oxygen. The first encapsulation layer may be formed of an inorganic material such as silicon nitride (SiNx), silicon oxy nitride (SiNxOy), or aluminum oxide (AlyOz), but is not limited thereto.

The second encapsulation layer is disposed on the first encapsulation layer to planarize a surface. Further, the second encapsulation layer may cover foreign materials or particles which may be generated during a manufacturing process of the display apparatus. The second encapsulation layer may be formed of an organic material, such as silicon oxy carbon SiOxCz, acryl or epoxy resin, but is not limited thereto.

The third encapsulation layer is disposed on the second encapsulation layer and suppresses the permeation of the moisture or oxygen, like the first encapsulation layer. The third encapsulation layer may be formed of an inorganic material such as silicon nitride (SiNx), silicon oxy nitride (SiNxOy), silicon oxide (SiOx), or aluminum oxide (AlyOz), but is not limited thereto.

An encapsulation substrate 125 is disposed on the encapsulation layer 124.

The encapsulation substrate 125 protects the organic light emitting diode 160 together with the encapsulation layer 124. The encapsulation substrate 125 may protect the organic light emitting diode 160 of the pixel unit 123 from moisture, oxygen, and impacts of the outside. The encapsulation substrate 125 may be formed of a metal material, which has a high corrosion resistance and is easily processed in the form of a foil or a thin film, such as aluminum (Al), nickel (Ni), chromium (Cr), and an alloy material of iron (Fe) and nickel. Therefore, as the encapsulation substrate 125 is formed of a metal material, the encapsulation substrate 125 may be implemented by an ultra-thin film and have a high resistance against external impacts and scratches but is not limited thereto.

As described above, according to the first exemplary embodiment of the present disclosure, the conductive pattern 150 is disposed below the substrate 121 in the non-display area NA and the edge area EA, for example, in a part of the upper portion of the barrier film 126 and grounded to supply (−) charges. By doing this, trapped (+) charges of the substrate 121 are offset and thus a burn-in of the edge may be improved.

In the meantime, according to the first exemplary embodiment of the present disclosure, the conductive pattern 150 is configured with a conductive tape as an example but is not limited thereto. According to the present disclosure, the conductive pattern may be configured with silver paste (Ag) coating, which will be described in detail with a following second exemplary embodiment of the present disclosure.

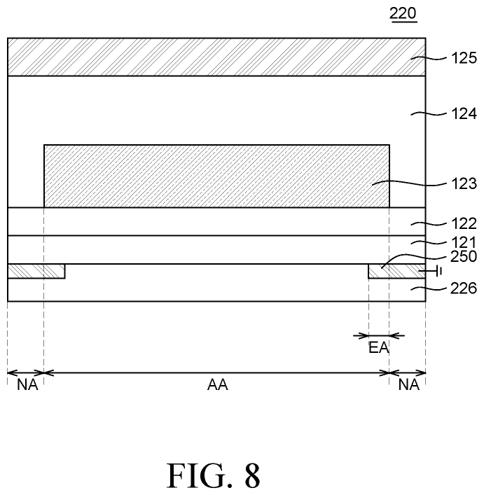

FIG. 8 is a schematic cross-sectional view of a display panel according to a second exemplary embodiment of the present disclosure.

As compared with the display panel 120 of FIG. 6, only a configuration of a conductive pattern 250 of a display panel 220 according to the second exemplary embodiment of the present disclosure of FIG. 8 is different, but other configurations are substantially the same, therefore, a redundant description will be omitted. The same configuration will be denoted with the same reference numeral.

Referring to FIG. 8, a display panel 220 according to a second exemplary embodiment of the present disclosure may include a display area AA and a non-display area NA.

A part of an edge of the display area AA may be defined as an edge area EA.

The edge area EA may have a width of 5 mm inwardly from the edge of the display area AA but is not limited thereto.

According to the second exemplary embodiment of the present disclosure, a conductive pattern 250 is formed in the edge area EA of the display panel 220.

That is, the conductive pattern 250 according to the second exemplary embodiment of the present disclosure may be formed below the substrate 121 in the non-display area NA and the edge area EA and grounded.

For example, the conductive pattern 250 may be disposed at one side or left and right sides of the display panel 220 in which a GIP area is disposed with a stripe pattern, but the present disclosure is not limited thereto. The conductive pattern 250 of the present disclosure may be disposed at the entire edge of the display panel 220 in the form of a rectangular frame.

The conductive pattern 250 may be disposed below the substrate 121 in the non-display area NA and the edge area EA, specifically, between the substrate 121 and the barrier film 226. For example, after the laser lift off (LLO) process, silver paste is coated on a rear surface of the substrate 121 at an outer periphery of the display panel 220 to form the conductive pattern 250 and a barrier film 226 may be laminated on the rear surface of the substrate 121 including the conductive pattern 250.

The conductive pattern 250 may be formed using silver paste by painting but is not limited thereto.

In the meantime, in the first and second exemplary embodiments of the present disclosure, the conductive patterns 150 and 250 are disposed at an outer periphery of the display panels 120 and 220 as an example, but the present disclosure is not limited thereto. According to the present disclosure, the conductive layer may be disposed on the entire rear surface of the substrate, which will be described in more detail with reference to a following third exemplary embodiment of the present disclosure.

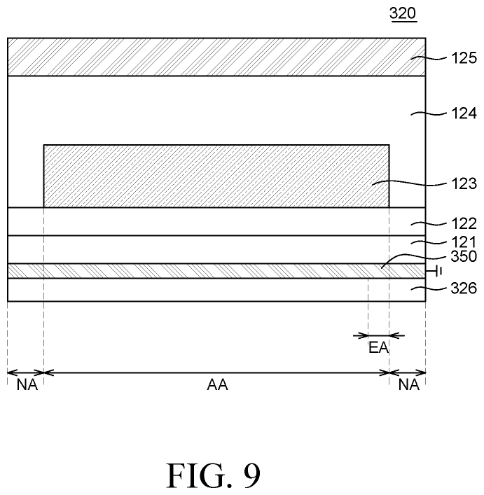

FIG. 9 is a schematic cross-sectional view of a display panel according to a third exemplary embodiment of the present disclosure.

As compared with the display panels 120 and 220 of FIGS. 6 and 8, only a configuration of a conductive layer 350 of a display panel 320 according to the third exemplary embodiment of the present disclosure of FIG. 9 is different, but other configurations are substantially the same. Therefore, a redundant description will be omitted.

Referring to FIG. 9, a display panel 320 according to a third exemplary embodiment of the present disclosure may include a display area AA and a non-display area NA.

According to the third exemplary embodiment of the present disclosure, a conductive layer 350 is formed on the entire display panel 320.

That is, the conductive layer 350 according to the third exemplary embodiment of the present disclosure may be formed on the entire display panel 320, that is, on the entire rear surface of the substrate 121, and may be grounded. The conductive layer 350 may be formed in the barrier film 326. The conductive layer 350 may be formed on a surface of the barrier film 326 by adding a conductive material into the barrier film 326. As an added material, a conductive ball may be included and the conductive layer may be formed of tin oxide (TO), indium tin oxide (ITO), indium zinc oxide (IZO), indium zinc tin oxide (ITZO), or the like.

In the meantime, according to the first, second, and third exemplary embodiments, the conductive patterns 150 and 250 or the conductive layer 350 are formed between the substrate 121 and the barrier films 126, 226, and 326 as an example, but the present disclosure is not limited thereto. According to the present disclosure, the conductive pattern may be disposed on a side surface of the substrate at the outer periphery of the display panel, which will be described in detail with following fourth and fifth exemplary embodiments of the present disclosure.

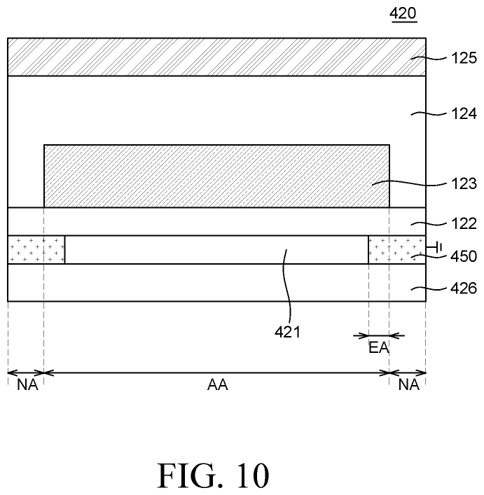

FIG. 10 is a schematic cross-sectional view of a display panel according to a fourth exemplary embodiment of the present disclosure.

As compared with the display panels 120 and 220 of FIGS. and 8, only configurations of a substrate 421 and a conductive pattern 450 of a display panel 420 according to a fourth exemplary embodiment of the present disclosure of FIG.

10 are different, but other configurations are substantially the same. Therefore, a redundant description will be omitted.

Referring to FIG. 10, a display panel 420 according to a fourth exemplary embodiment of the present disclosure may include a display area AA and a non-display area NA.

A part of an edge of the display area AA may be defined as an edge area EA.

The edge area EA may have a width of 5 mm inwardly from the edge of the display area AA but is not limited thereto.

According to the fourth exemplary embodiment of the present disclosure, a conductive pattern 450 is formed in the edge area EA of the display panel 420. That is, the conductive pattern 450 according to the fourth exemplary embodiment of the present disclosure may be formed on a side surface of a substrate 421 in the non-display area NA and the edge area EA, and may be grounded.

For example, the conductive pattern 450 may be disposed at one side or left and right sides of the display panel 420 in which a GIP area is disposed with a stripe shape, but the present disclosure is not limited thereto. The conductive pattern 450 of the present disclosure may be disposed at the entire edge of the display panel 420 in the form of a rectangular frame.

The conductive pattern 450 may be formed on the side surface of the substrate 421 in the non-display area NA and the edge area EA. That is, for example, the substrate 421 is formed by etching the side surface of the substrate 421 in the non-display area NA and the edge area EA or selectively coating polyimide in other areas of the display panel 420 than the non-display area NA and the edge area EA, and then the conductive material is deposited on the side surface of the substrate 421 to form a conductive pattern 450.

As a conductive material, tin oxide (TO), indium tin oxide (ITO), indium zinc oxide (IZO), indium zinc tin oxide (ITZO), or the like may be used.

Thereafter, a barrier film 426 may be laminated on the rear surface of the substrate 421 and the conductive pattern 450.

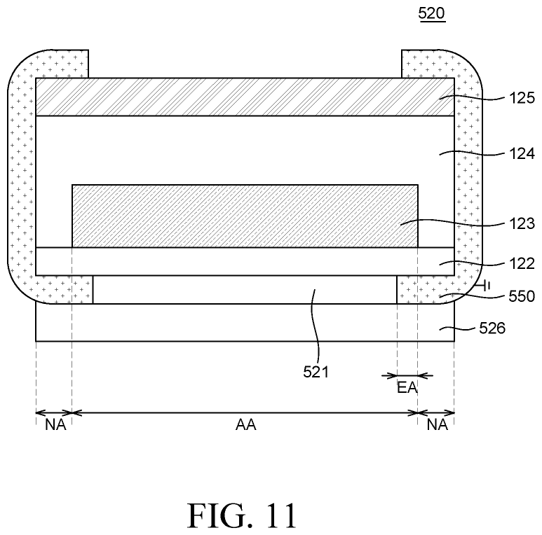

FIG. 11 is a schematic cross-sectional view of a display panel according to a fifth exemplary embodiment of the present disclosure.

As compared with the display panel 420 of FIG. 10, only a configuration of a conductive pattern 550 of a display panel 520 according to a fifth exemplary embodiment of the present disclosure of FIG. 11 is different, but other configurations are substantially the same. Therefore, a redundant description will be omitted.

Referring to FIG. 11, a display panel 520 according to a fifth exemplary embodiment of the present disclosure may include a display area AA and a non-display area NA.

A part of an edge of the display area AA may be defined as an edge area EA.

The edge area EA may have a width of 5 mm inwardly from the edge of the display area AA, but is not limited thereto.

According to the fifth exemplary embodiment of the present disclosure, a conductive pattern 550 is formed in the edge area EA of the display panel 520. Specifically, the conductive pattern 550 according to the fifth exemplary embodiment of the present disclosure is formed on a side surface of a substrate 521 in the non-display area NA and the edge area EA and extends to an upper portion along a side surface of a display panel 520, and the conductive pattern 550 is grounded.

The conductive pattern 550 according to the fifth exemplary embodiment of the present disclosure may be disposed at one side or left and right sides of the display panel 520 in which a GIP area is disposed or disposed at the entire edge of the display panel 520 in the form of a rectangular frame.

In addition, according to the fifth exemplary embodiment of the present disclosure, a substrate 521 is formed by etching a side surface of the substrate 521 in the non-display area NA and an edge area EA or selectively coating polyimide in other areas of the display panel 520 than the non-display area NA and the edge area EA. Thereafter, a conductive material is sprayed on a side surface of the display panel 520 including the side surface of the substrate 521 to form a conductive pattern 550.

Thereafter, a barrier film 526 is laminated on the rear surface of the substrate 521 and the conductive pattern 550.

In the meantime, when a (−) bias is applied to the GIP area to perform an off-driving of the transistor, an active back channel is formed by charges accumulated on a surface of a polyimide substrate. That is, during the gate driving, charges are accumulated on the surface of the polyimide substrate due to the (−) bias to cause the polarization. Therefore, an active back channel is formed so that the threshold voltage Vth shift of the transistor is generated. A short path of the current is formed so that voltage drop is generated and a Qb node is abnormally operated, which may cause the driving failure.

Therefore, according to the present disclosure, a part of the polyimide substrate below the transistor in the GIP area is removed or a shielding layer is formed to suppress the driving failure in the GIP area. By doing this, a threshold voltage shift of the transistor in the GIP area is improved and the high potential power voltage drop is improved to improve the reliability of the driving circuit.

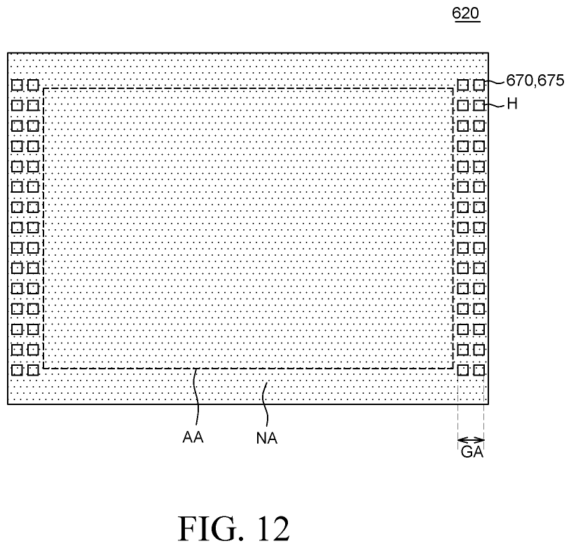

FIG. 12 is a schematic plan view of a display panel according to a sixth exemplary embodiment of the present disclosure.

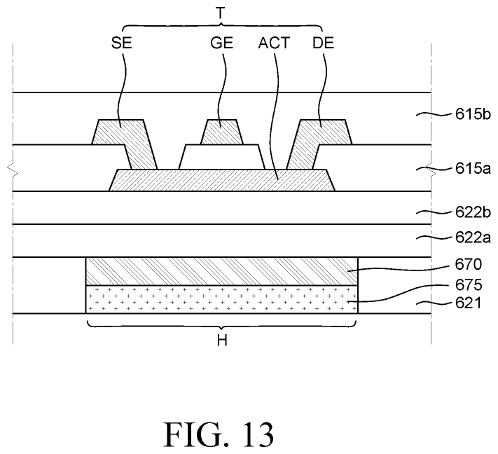

FIG. 13 is a cross-sectional view of a part of a GIP area according to a sixth exemplary embodiment of the present disclosure.

In FIG. 12, for the convenience of description, transistors T in a GIP area GA and grooves H therebelow are regularly disposed in rows and columns as an example, but the present disclosure is not limited thereto. In FIG. 13, for the convenience of description, a cross-section of a GIP area GA including one transistor T is illustrated as an example. For example, in FIG. 13, some configurations including configurations above a second insulating layer 615b are omitted.

Referring to FIGS. 12 and 13, a display panel 620 according to a sixth exemplary embodiment of the present disclosure may include a display area AA and a non-display area NA.

The display area AA is an area where images are displayed in the display panel 620.

The non-display area NA is an area where an image is not displayed and may be adjacent to one or more side surfaces of the display area AA.

The non-display area NA may include a GIP area GA in which a gate driver is disposed.

The GIP area GA may be disposed on at least one side of the display panel 620 but is not limited thereto. In FIG. 12, it is illustrated that the GIP area GA is disposed at left and right sides of the display panel 620 as an example but is not limited thereto.

In the meantime, the display apparatus according to the sixth exemplary embodiment of the present disclosure forms a groove H by removing a part of the polyimide substrate 621 below the transistor T in the GIP area GA of the display panel 620 and fills the groove H with predetermined filling layers 670 and 675.

Specifically, the substrate 621 may be a glass or plastic substrate. When the substrate is a plastic substrate, polyimide-based or polycarbonate-based materials are used so that the substrate may have a flexibility. Specifically, polyimide may be applied to a high temperature process and may be coated, and thus polyimide may be frequently used for the plastic substrate.

The buffer layers 622a and 622b are functional layers which protect the transistors from impurities such as alkali ions, moisture and/or oxygen leaked from the substrate 621 or lower layers thereof. The buffer layers 622a and 622b may be configured by a single layer of silicon oxide (SiOx), silicon nitride (SiNx), or multi-layers thereof, but is not limited thereto. The buffer layers 622a and 622b may include a multi buffer layer 622a and/or an active buffer layer 622b. The multi-buffer layer 622a may be configured by alternately laminating silicon oxide (SiOx) and silicon nitride (SiNx) and performs a function of delaying the diffusion of moisture and/or oxygen permeated into the substrate 621. The active buffer layer 622b protects an active layer ACT of the transistor T and performs a function of blocking various types of defects flowing from the substrate 621.

At least one transistor T may be disposed on the buffer layers 622a and 622b.

The transistor T may include an active layer ACT, a gate electrode GE, a source electrode SE, and a drain electrode DE.

The active layer ACT may be disposed on the buffer layers 622a and 622b.

The active layer ACT may be formed of an oxide semiconductor material. However, it is not limited thereto, for example, the active layer ACT may be formed of an amorphous silicon (a-Si), polycrystalline silicon or various organic semiconductor materials such as pentacene.

A first insulating layer 615a is disposed on the active layer ACT and a gate electrode GE, a source electrode SE, and a drain electrode DE may be disposed on the first insulating layer 615a, but the present disclosure is not limited thereto, and the source electrode SE and the drain electrode DE may be disposed on a different layer from the gate electrode GE.

A first insulating layer 615a may be configured as a single layer of silicon nitride SiNx or silicon oxide SiOx or a multi-layer thereof.

The gate electrode GE, the source electrode SE, and the drain electrode DE may be formed of various conductive materials, for example, magnesium (Mg), aluminum (Al), nickel (Ni), chrome (Cr), molybdenum (Mo), tungsten (W), gold (Au), or an alloy thereof, but is not limited thereto.

A second insulating layer 615b may be disposed above the gate electrode GE, the source electrode SE, and the drain electrode DE.

The second insulating layer 615b may be formed of an insulating inorganic material such as silicon oxide SiOx or silicon nitride SiNx or an insulating organic material.

In the meantime, the substrate 621 is completely removed and a groove H is disposed, below the transistor T in the GIP area GA. That is, the substrate 621 below the active layer ACT of the transistor T is completely removed to fundamentally suppress the charges accumulated on the surface of the substrate 621 and the voltage drop.

The groove H may have a similar shape to the planar shape of the transistor T but is not limited thereto. The groove H may have a rectangular shape including the transistor T.

The groove H is a portion where the substrate 621 below the transistor T of the GIP area GA is completely removed and the groove H may be filled with filling layers 670 and 675.

The filling layers 670 and 675 may include a first filling layer 670 in contact with the multi buffer layer 622a and a second filling layer 675 in contact with the first filling layer 670.

The first filling layer 670 may be configured as a single layer of silicon oxide SiOx, silicon nitride SiNx or silicon oxy nitride SiON or a multi-layer thereof.

The second filling layer 675 may be formed of at least one selected from acryl, acrylic oligomer, epoxy, and urethane, but is not limited thereto.

Hereinafter, a process of forming the groove H and the filling layers 670 and 675 on the substrate 621 will be described in more detail with reference to the drawings.

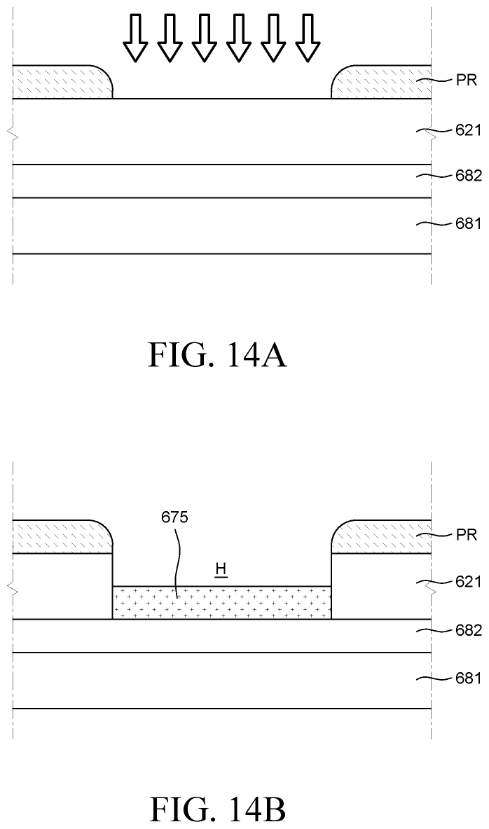

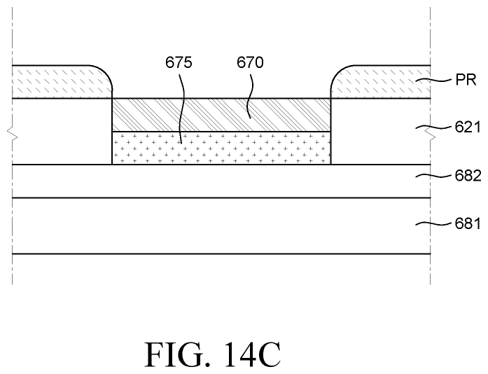

FIGS. 14A to 14C are cross-sectional views sequentially illustrating a manufacturing method of FIG. 13.

First, referring to FIG. 14A, a substrate 621 may be formed on a support substrate 681 with a sacrificial layer 682 therebetween.

The substrate 621 is a base member which supports various components of the display panel and may be configured by an insulating material. The substrate 621 may be formed of a material having a flexibility to allow the display panel to be wound or unwound and for example, may be formed of a plastic material such as polyimide (PI). That is, in order to implement a flexible display apparatus, a flexibility of the substrate 621 needs to be ensured and currently, in order to ensure the flexibility of the substrate, a plastic flexible substrate 621 may be used instead of the glass substrate of the related art.

When the substrate 621 is formed of a flexible material such as polyimide, the support substrate 681 may be attached to a lower portion of the substrate 621 to easily perform the subsequent process.

The support substrate 681 may be formed of glass but is not limited thereto.

The support substrate 681 may be separated from the substrate 621 by releasing the sacrificial layer 682 by a laser releasing process. The sacrificial layer 682 may be formed by amorphous silicon (a-Si) or a silicon nitride SiNx film.

Next, a predetermined photoresist pattern PR may be formed on the substrate 621.

The photoresist pattern PR is patterned by a photolithographic process and for example, when a positive type photoresist is used, a portion where the transistor of the GIP area is located, that is, a portion where the groove is to be formed is exposed to be removed, but the present disclosure is not limited thereto.

Next, referring to FIG. 14B, a partial area of the substrate 621 is etched by means of the photoresist pattern PR to form a groove H in a portion where a transistor of the GIP area is to be formed.

The groove H may be formed to expose the sacrificial layer 682 below the substrate 621 by completely removing the substrate 621.

Next, the second filling layer 675 is formed in the groove H with a predetermined thickness.

The second filling layer 675 may be formed of at least one selected from acryl, acrylic oligomer, epoxy, and urethane, but is not limited thereto.

The second filling layer 675 may serve to suppress the buckling of the substrate 621 caused when the support substrate 681 is released.

Next, referring to FIG. 14C, the first filling layer 670 is filled in the groove H filled with the second filling layer 675.

The first filling layer 670 may be configured as a single layer of silicon oxide SiOx, silicon nitride SiNx or silicon oxy nitride SiON or a multi-layer thereof.

The first filling layer 670 may serve to enhance the adhesiveness between the second filling layer 675 and a layer formed on the substrate 621.

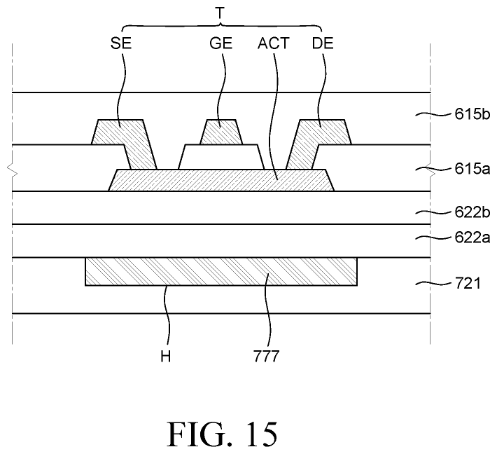

FIG. 15 is a cross-sectional view of a part of a GIP area according to a seventh exemplary embodiment of the present disclosure.

As compared with the sixth exemplary embodiment of FIG. 13, only configurations of a groove H and a light shielding layer 777 of a seventh exemplary embodiment of the present disclosure of FIG. 15 are different, but the other configurations are substantially the same. Therefore, a redundant description will be omitted. The same configuration will be denoted with the same reference numeral.

Similar to the sixth exemplary embodiment of the present disclosure described above, in FIG. 15, for the convenience of description, a cross-section of a GIP area GA including one transistor T is illustrated as an example. For example, in FIG. 15, some configurations including configurations above a second insulating layer 615b are omitted.

Referring to FIG. 15, a display apparatus according to the seventh exemplary embodiment of the present disclosure forms a groove H by removing a part of a thickness of a polyimide substrate 721 below the transistor T in the GIP area GA and fills a groove H with a predetermined light shielding layer 777.

A part of the thickness of the substrate 721 is removed below the transistor T of the GIP area GA to form the groove H and the groove H is filled with the light shielding layer 777 to suppress the formation of the electric field between the active layer ACT and the substrate 721. Therefore, the charges accumulated on the surface of the substrate 721 and the voltage drop may be suppressed.

The groove H may have a similar shape to the planar shape of the transistor T but is not limited thereto. The groove H may have a rectangular shape including the transistor T.

The groove H is a portion where a thickness of the substrate 721 below the transistor T of the GIP area GA is partially removed, and the groove H may be filled with the light shielding layer 777.

The light shielding layer 777 may be in contact with the multi buffer layer 622a.

The light shielding layer 777 may be formed of tin oxide (TO), indium tin oxide (ITO), indium zinc oxide (IZO), indium zinc tin oxide (ITZO), or the like to suppress the formation of the electric field between the active layer ACT and the substrate 721 but is not limited thereto.

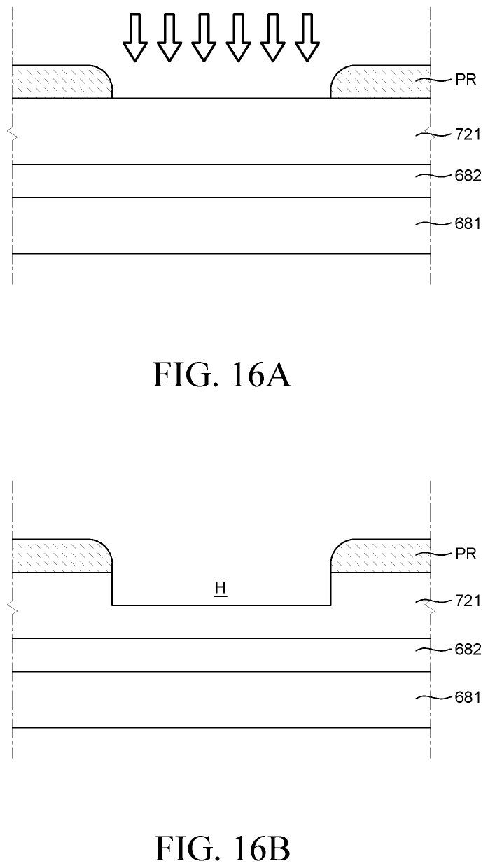

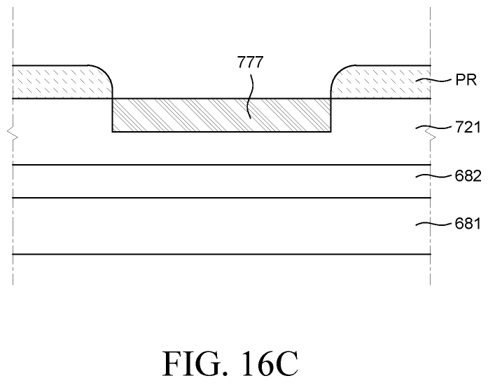

FIGS. 16A to 16C are cross-sectional views sequentially illustrating a manufacturing method of FIG. 15.

First, referring to FIG. 16A, a substrate 721 is formed on a support substrate 681 with a sacrificial layer 682 therebetween.

Next, a predetermined photoresist pattern PR may be formed on the substrate 721.

Next, referring to FIG. 16B, a part of a thickness of the substrate 721 is etched by means of the photoresist pattern PR to form a groove H in a portion where a transistor of the GIP area is to be formed.

Next, referring to FIG. 16C, the groove H is filled with the light shielding layer 777.

The light shielding layer 777 may be formed of tin oxide (TO), indium tin oxide (ITO), indium zinc oxide (IZO), indium zinc tin oxide (ITZO), or the like, but is not limited thereto.

In the meantime, the groove H of the present disclosure may be individually provided for one transistor T below the GIP area GA, but is not limited thereto, for example, it may be formed to correspond to a plurality of transistors T or formed to correspond to the entire GIP area GA.

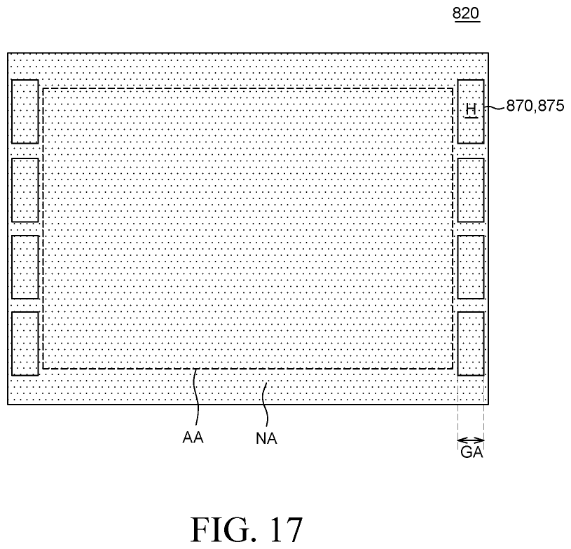

FIG. 17 is a schematic plan view of a display panel according to an eighth exemplary embodiment of the present disclosure.

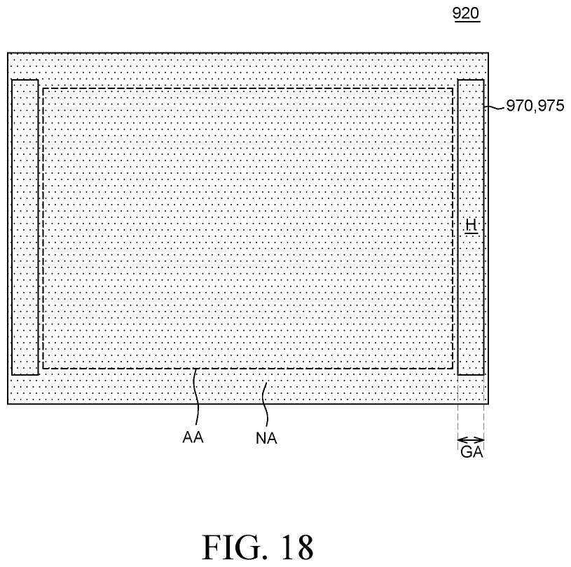

FIG. 18 is a schematic plan view of a display panel according to a ninth exemplary embodiment of the present disclosure.

As compared with the display panel 620 of FIG. 12, only a configuration of a groove H of display panels 820 and 920 of

FIGS. 17 and 18 is different, but other configurations are substantially the same. Therefore, a redundant description will be omitted. The same configuration will be denoted with the same reference numeral.

Referring to FIGS. 17 and 18, display panels 820 and 920 according to eighth and ninth exemplary embodiments of the present disclosure may include a display area AA and a non-display area NA.

The non-display area NA may include a GIP area GA in which a gate driver is disposed.

The GIP area GA is disposed on at least one side of the display panels 820 and 920 but is not limited thereto. In FIGS. 17 and 18, it is illustrated that the GIP area GA is disposed at left and right sides of the display panels 820 and 920 as an example but is not limited thereto.

In the meantime, a display apparatus according to the eighth exemplary embodiment of the present disclosure forms a groove H by removing a part of the polyimide substrate 621 below a plurality of transistors T in the GIP area GA of the display panel 820 and fills the groove H with predetermined filling layers 870 and 875.

The groove H according to the eighth exemplary embodiment of the present disclosure may be formed to correspond to a plurality of transistors T and the groove H may be filled with the filling layers 870 and 875. That is, the groove H may be provided in a broad range of the GIP area GA occupied by the plurality of transistors T.

The groove H according to the eighth exemplary embodiment of the present disclosure may be formed by completely removing the substrate in the GIP area GA occupied by the plurality of transistors T, but is not limited thereto, and may be formed by removing only a part of a thickness of the substrate.

Further, a display apparatus according to a ninth exemplary embodiment of the present disclosure forms a groove H by removing the polyimide substrate corresponding to the entire GIP area GA of the display panel 920 and fills the groove H with predetermined filling layers 970 and 975.

The groove H according to the ninth exemplary embodiment of the present disclosure may be formed to correspond to the entire GIP area GA and the groove H may be filled with the filling layers 970 and 975.

The groove H according to the ninth exemplary embodiment of the present disclosure may be formed by completely removing the substrate corresponding to the entire GIP area GA, but the present disclosure is not limited thereto, and the groove H may be formed by removing only a part of a thickness of the substrate.

The filling layers 870, 970 and 875, 975 may include first filling layers 870 and 970 in contact with the multi buffer layer 622a and second filling layers 875 and 975 in contact with the first filling layers 870 and 970.

The first filling layers 870 and 970 may be configured as a single layer of silicon oxide SiOx, silicon nitride SiNx or silicon oxy nitride SiON or a multi-layer thereof.

The second filling layers 875 and 975 may be formed of at least one selected from acryl, acrylic oligomer, epoxy, and urethane, but are not limited thereto.

When the groove H is formed by removing only a part of a thickness of the substrate, the groove H may be filled with a predetermined light shielding layer.

The light shielding layer may be formed of tin oxide (TO), indium tin oxide (ITO), indium zinc oxide (IZO), indium zinc tin oxide (ITZO), or the like to suppress the formation of the electric field between the active layer ACT and the substrate 721 but is not limited thereto.

The exemplary embodiments of the present disclosure can also be described as follows:

According to an aspect of the present disclosure, there is provided a display apparatus. The display apparatus includes a display panel which is divided into a display area and a non-display area and includes a substrate, a pixel unit transistor which is disposed above the substrate and provided in the display area and a gate in panel (GIP) transistor which is provided in the non-display area, a conductive pattern which is disposed below the substrate and is disposed in an edge area of the display area and the non-display area and which is grounded and a barrier film which is disposed below the substrate and the conductive pattern.

According to another aspect of the present disclosure, there is provided a display apparatus. The display apparatus includes a display panel which is divided into a display area and a non-display area and includes a substrate, a pixel unit transistor which is disposed above the substrate and provided in the display area and a gate in panel (GIP) transistor which is provided in a GIP area of the non-display area, a conductive pattern which is disposed on a side surface of the substrate and is disposed in an edge area of the display area and the non-display area and which is grounded and a barrier film which is disposed below the substrate and the conductive pattern.

The display apparatus may further include a back cover disposed on a rear surface of the display panel and a roller which is connected to the back cover to wind or unwind the back cover and the display panel.

The substrate may be made of polyimide.

The conductive pattern may be formed in at least one side of the display panel with a stripe shape.

The conductive pattern may be formed in an entire edge of the display panel in the form of a rectangular frame.

A light shielding layer may be disposed below the pixel unit transistor, but the light shielding layer may be not disposed below the GIP transistor and the grounded conductive pattern offsets (+) charges trapped in the edge area of the display area by irregularity of an electric field depending on placement of the light shielding layer.

The conductive pattern may be disposed to extend from the edge area of the display area to the non-display area.

The conductive pattern may be configured by a conductive tape or silver paste (Ag paste).

The conductive pattern may be disposed on an entire lower surface of the substrate and be made of tin oxide (TO), indium tin oxide (ITO), indium zinc oxide (IZO), or indium zinc tin oxide (ITZO).

The conductive pattern may extend along a side surface of the display panel to an upper portion of the display panel.

According to still another aspect of the present disclosure, there is provided a display apparatus. The display apparatus includes a display panel which is divided into a display area and a non-display area and includes a substrate, a GIP transistor which is disposed above the substrate and is provided in a GIP area of the non-display area, a groove provided in the substrate below the GIP transistor and a filling layer provided in the groove.

The substrate may be made of polyimide.

The groove may be formed by completely removing a portion of the substrate corresponding to the GIP transistor.

The groove may be formed by removing a portion of a thickness of the substrate corresponding to the GIP transistor.

The groove may have a planar shape corresponding to a planar shape of the GIP transistor.

The filling layer may be configured by a first filling layer which is in contact with a buffer layer and a second filling layer which is in contact with the first filling layer, the first filling layer may be configured as a single layer of silicon oxide SiOx, silicon nitride SiNx or silicon oxy nitride SiON or a multi-layer thereof, and the second filling layer may be configured by at least any one selected from acryl, acrylic oligomer, epoxy, and urethane.

The filling layer may be made of tin oxide (TO), indium tin oxide (ITO), indium zinc oxide (IZO), or indium zinc tin oxide (ITZO) to configure a light shielding layer.

The groove may have a planar shape corresponding to a plurality of GIP transistors.

The groove may have a planar shape corresponding to the entire GIP area.

It will be apparent to those skilled in the art that various modifications and variations can be made in the display apparatus of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display apparatus, comprising:
a display panel which is divided into a display area and a non-display area and includes a substrate;
a pixel unit transistor which is disposed above the substrate and provided in the display area;
a gate in panel (GIP) transistor which is provided in the non-display area;
a conductive pattern which is disposed below the substrate and is disposed in an edge area of the display area and the non-display area and which is grounded; and
a barrier film which is disposed below the substrate and the conductive pattern.

2. A display apparatus, comprising:
a display panel which is divided into a display area and a non-display area and includes a substrate;
a pixel unit transistor which is disposed above the substrate and provided in the display area;
a gate in panel (GIP) transistor which is provided in a GIP area of the non-display area;
a conductive pattern which is disposed on a side surface of the substrate and is disposed in an edge area of the display area and the non-display area and which is grounded; and
a barrier film which is disposed below the substrate and the conductive pattern.

3. The display apparatus according to claim 1, further comprising:
a back cover disposed on a rear surface of the display panel; and
a roller which is connected to the back cover to wind or unwind the back cover and the display panel.

4. The display apparatus according to claim 3, wherein the substrate is made of polyimide.

5. The display apparatus according to claim 3, wherein the conductive pattern is formed in at least one side of the display panel with a stripe shape.

6. The display apparatus according to claim 3, wherein the conductive pattern is formed in an entire edge of the display panel in the form of a rectangular frame.

7. The display apparatus according to claim 3, wherein a light shielding layer is disposed below the pixel unit transistor, but the light shielding layer is not disposed below the GIP transistor and the grounded conductive pattern offsets (+) charges trapped in the edge area of the display area by irregularity of an electric field depending on placement of the light shielding layer.

8. The display apparatus according to claim 3, wherein the conductive pattern is disposed to extend from the edge area of the display area to the non-display area.

9. The display apparatus according to claim 3, wherein the conductive pattern is configured by a conductive tape or silver paste (Ag paste).

10. The display apparatus according to claim 1, wherein the conductive pattern is disposed on an entire lower surface of the substrate and is made of tin oxide (TO), indium tin oxide (ITO), indium zinc oxide (IZO), or indium zinc tin oxide (ITZO).

11. The display apparatus according to claim 2, wherein the conductive pattern extends along a side surface of the display panel to an upper portion of the display panel.

12. A display apparatus, comprising:
a display panel which is divided into a display area and a non-display area and includes a substrate;
a GIP transistor which is disposed above the substrate and is provided in a GIP area of the non-display area;
a groove provided in the substrate below the GIP transistor; and
a filling layer provided in the groove.

13. The display apparatus according to claim 12, wherein the substrate is made of polyimide.

14. The display apparatus according to claim 12, wherein the groove is formed by completely removing a portion of the substrate corresponding to the GIP transistor.

15. The display apparatus according to claim 12, wherein the groove is formed by removing a portion of a thickness of the substrate corresponding to the GIP transistor.

16. The display apparatus according to claim 12, wherein the groove has a planar shape corresponding to a planar shape of the GIP transistor.

17. The display apparatus according to claim 12, wherein the filling layer is configured by a first filling layer which is in contact with a buffer layer disposed below the GIP transistor and a second filling layer which is in contact with the first filling layer, the first filling layer is configured as a single layer of silicon oxide (SiOx), silicon nitride (SiNx) or silicon oxy nitride (SiON) or a multi-layer thereof, and the second filling layer is configured by at least any one selected from acryl, acrylic oligomer, epoxy, and urethane.

18. The display apparatus according to claim 12, wherein the filling layer is made of tin oxide (TO), indium tin oxide (ITO), indium zinc oxide (IZO), or indium zinc tin oxide (ITZO) to configure a light shielding layer.

19. The display apparatus according to claim 12, wherein the groove has a planar shape corresponding to a plurality of GIP transistors.

20. The display apparatus according to claim 12, wherein the groove has a planar shape corresponding to the entire GIP area.
